(19) United States
(12) Patent Application Publication
(10) Pub. No.: US 2010/0140679 A1
(43) Pub. Date: Jun. 10, 2010

(54) STACKED DUAL-GATE NMOS DEVICES WITH ANTIMONY SOURCE-DRAIN REGIONS AND METHODS FOR MANUFACTURING THEREOF

(76) Inventor: Andrew J. Walker, Mountain View, CA (US)

Correspondence Address: HAYNES AND BOONE, LLP;IP Section, 2323 Victory Avenue, Suite 700, Dallas, TX, 75219, US

(21) Appl. No.: 12/329,477

(22) Filed: Dec. 5, 2008

(51) Int. Cl. H01L 29/788

(52) U.S. Cl. 257/316; 257/E29.3

(57) ABSTRACT

A three-dimensional memory structure includes multiple layers of memory devices, each memory device including a dual-gate device. A dual-gate device includes an active layer between a first gate structure and a second gate structure. Each gate structure is isolated from the active layer by a dielectric layer and is located above a semiconductor or channel region in the active layer defined by spaced-apart diffusion regions formed by implanting antimony ions. The antimony-doped diffusion regions are particularly suitable in stacked memory devices because antimony can be implanted and activated at a temperature less than 900° C. and show little movement of the implanted antimony ions even after numerous thermal steps in the manufacturing process. As a result, dual-gate devices in a stacked memory device with well-controlled channel lengths may be achieved.

### CROSS-REFERENCE TO RELATED APPLICATIONS

The present patent application is related to and claims priority of the following copending U.S. patent applications: (a) U.S. patent application, entitled “DUAL-GATE DEVICE AND METHOD” (“Copending Application I”), Ser. No. 11/197,462, filed on Aug. 3, 2005, and (ii) U.S. patent application, entitled “Dual-Gate NMOS Devices with Antimony Source-Drain Regions and Methods for Manufacturing Thereof” (“Copending Application II”), Ser. No. 11/749,078, filed on May 15, 2007.” The disclosures of the Copending Application I and Copending Application II are hereby incorporated by reference in their entireties

### BACKGROUND OF THE INVENTION

1. Field of the Invention

The present invention relates to semiconductor devices. In particular, the present invention relates to dopant selection for semiconductor devices with stringent diffusion region alignment requirements, such as three-dimensional memory arrays.

2. Discussion of the Related Art

Dual-gate devices have been proposed to achieve high density integrated circuits (e.g., non-volatile memories). Examples of dual-gate devices and their use may be found in the Copending Application I.

### SUMMARY OF THE INVENTION

According to the present invention, a three-dimensional memory structure includes multiple layers of memory devices, each memory device including a dual-gate device. The dual gate device includes an active layer between a first gate structure and a second gate structure. Each gate structure is isolated from the active layer by a dielectric layer and is located above a semiconductor or channel region in the active layer defined by spaced-apart diffusion regions formed by implanting antimony ions. The antimony-doped diffusion regions are particularly suitable for manufacturing stacked memory devices because antimony can be implanted and activated at a temperature less than 900° C. and show little movement of the implanted antimony ions even after numerous thermal steps in the manufacturing process. As a result, the dual-gate devices in such a stacked memory device with well-controlled channel lengths may be achieved.

The present invention is better understood upon consideration of the detailed description below in conjunction with the accompanying drawings.

### BRIEF DESCRIPTION OF THE DRAWINGS

FIG. 1 shows the sheet resistance of amorphous silicon into which antimony has been implanted as a function of activation temperature.

FIG. 2 shows antimony profiles after implantation and anneal steps.

FIGS. 3A-3L illustrate a method suitable for forming a NAND-type non-volatile semiconductor memory device using antimony, according to one embodiment of the present invention.

FIG. 4 shows a 3-D stack of dual-gate memory cells (3 layer), illustrating that the implanted antimony dopant profile is substantially retained in each layer over the various temperature cycles experienced in their fabrication.

### DETAILED DESCRIPTION OF THE PREFERRED EMBODIMENT

One issue relevant to creating NMOS-based nonvolatile memories in three dimensions (3-D) relates to, when multiple device levels are formed, the multiple implantations of N-type source-drain dopants and their respective activations. Some examples of 3-D memory structures with multiple levels of devices are provided in Copending Application I. The addition of several layers of memory cells monolithically stacked in 3-D increases the total thermal steps in a process, with the following consequences: (a) the underlying circuitry (e.g., bulk CMOS driving circuitry) experiences as many times the temperature steps required for each memory cell layer as the total number of memory cell layers in the 3-D stack; and (b) each memory cell layer experiences all the temperature steps required for fabricating all the other memory cell layers above it.

As each temperature step causes dopants in the bulk and in any already fabricated memory cell layers to diffuse—the effects of which are especially important for the source-drain regions—it becomes difficult to manufacture short channel length bulk transistors and memory devices (both NMOS and PMOS). Further, because each memory cell layer experiences a different number of thermal cycles, depending on the vertical position of the memory cell in the 3-D stack, variations in memory cell behavior may result.

Mathematically, the dopant diffusion characteristics can be understood using the diffusion coefficient D of any of the dopants used. For example, the total ( D̅·t) product for the diffusion of antimony in the first memory layer is given by:

$$( \overline{D} \cdot t ) = {\sum }_{i = 2}^{N} ( {D}_{i} \cdot {t}_{i} )$$

where N is the total number of memory cell layers; and Dᵢ and tᵢ are the effective diffusion coefficient and time associated with the processing of the i^{th} memory layer. See, e.g., “Introduction to Microelectronic Fabrication,” by Richard Jaeger, Modular Series on Solid State Devices, vol. V, p. 57, Addison-Wesley, publisher, 1988; ISBN 0-201-14695-9. Clearly, monolithic 3-D integration increases the Dt product for any dopants in the bulk or low down in the memory stack.

In addition, for three-dimensional memory structures including dual-gate devices, further dopant distribution constraints are present. This is because alignment between the top gate and the bottom gate of a dual-gate device within stringent tolerance limits is required for correct operation, the implantation step that creates the source-drain diffusion regions in such a device is more critical than the corresponding implantation step for creating source-drain diffusion regions in a conventional single-gate device. Several approaches have been proposed to avoid misalignment between the top gate and the bottom gate. As the top gate is typically used as the source-drain implantation mask, one suggestion is to make the top gate smaller than the bottom gate. In addition, an angled implantation may then be used to create the source-drain regions. However, such an approach leads to an effectively smaller channel length in the dual-gate device relative to a single-gate device of comparable dimensions. As a result, the properties of implanted junctions must be precisely controlled in a dual-gate device, especially during steps performed at an elevated temperature, such as thermal activation (e.g., dopant diffusion and activation). Otherwise, lateral dopant movement may cause the dual-gate device to have an even shorter channel length, which renders it vulnerable to undesirable source-drain punchthrough during operation.

A process for manufacturing 3-dimensional semiconductor structures integrating dual-gate devices therefore faces more stringent limitations in its thermal budget than a process manufacturing only single-gate devices. Steps associated with thermal activities are encountered in each added device layer. For example, steps with thermal activities include gate dielectric formation and dopant activation. These thermal steps are experienced multiple times in manufacturing a dual-gate device, whose channel length is already inherently smaller than its single-gate counterpart in the first place. In such a device, dopant movement (e.g., by diffusion) is even more critical to the device's performance.

According to the present invention, antimony is found to be an n-type dopant species that has the following desirable attributes suitable for use in a dual-gate device with NMOS source-drain regions:

Low temperature (below ˜850° C.) thermal activation;

Little or no dopant diffusion during activation and during any other thermal steps experienced by the dopant.

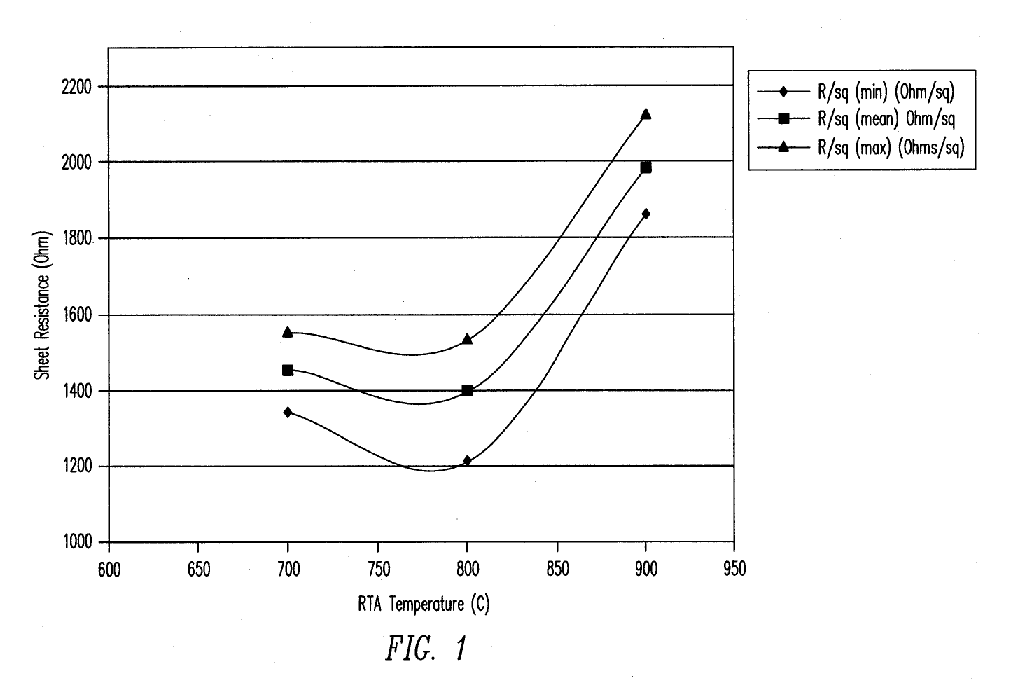

FIG. 1 shows the sheet resistance of polysilicon into which antimony has been implanted as a function of activation temperature. For each activation temperature, many sites across a 200 mm wafer were measured. The mean, minimum and maximum sheet resistances for each activation temperature are shown in FIG. 1. The activation for each wafer was carried out by a 30-second rapid thermal annealing (RTA) step for the specified temperature in a nitrogen ambient. FIG. 1 shows that better activation may be achieved at temperatures below about 850° C. than at temperatures above 850 ° C.

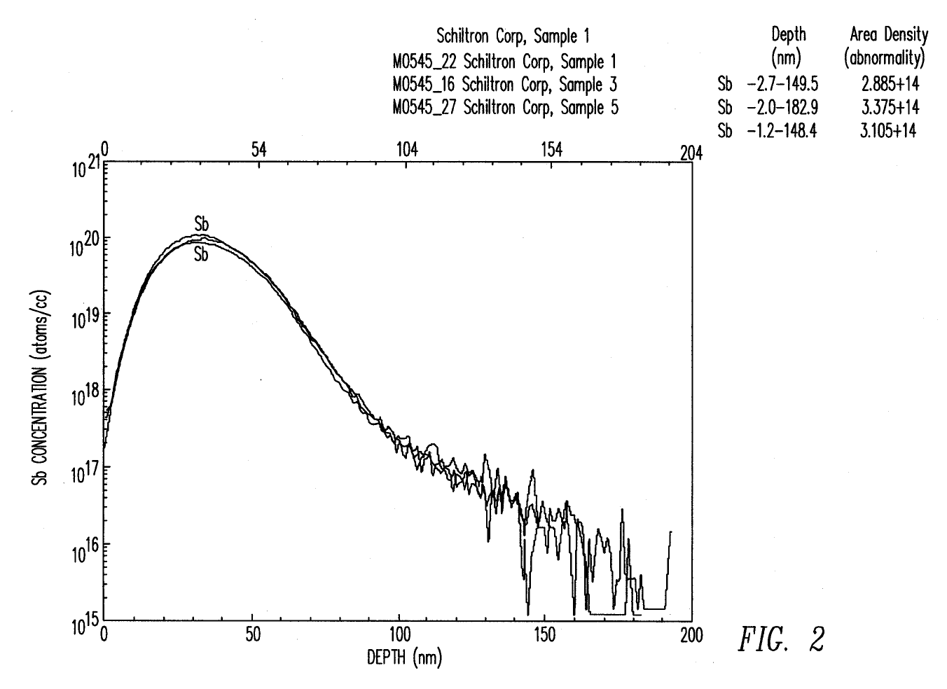

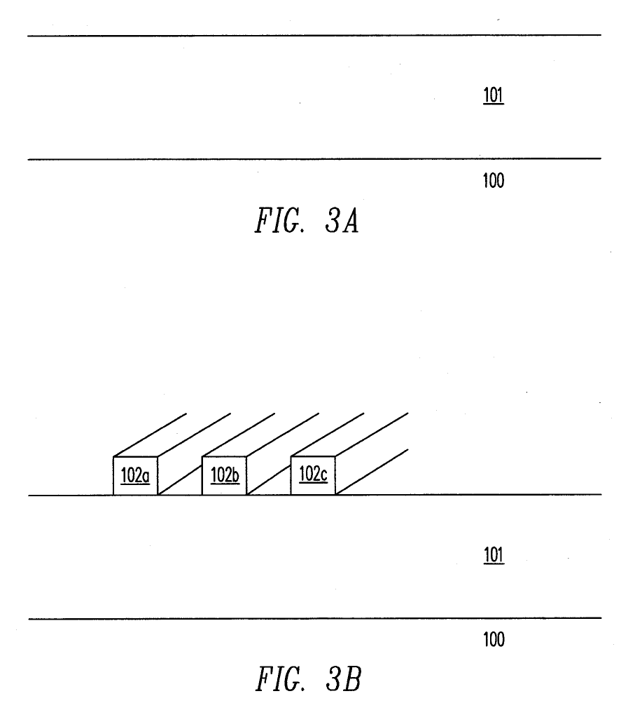

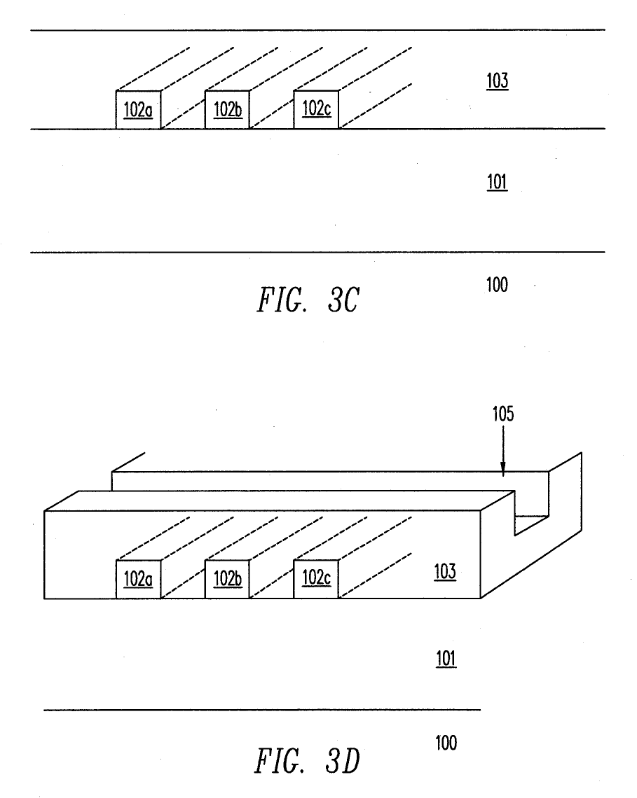

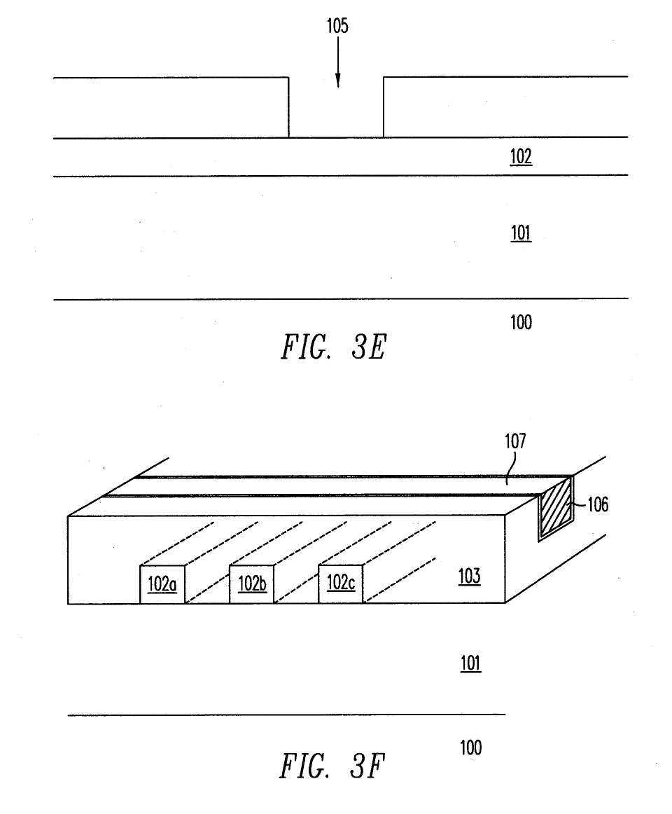

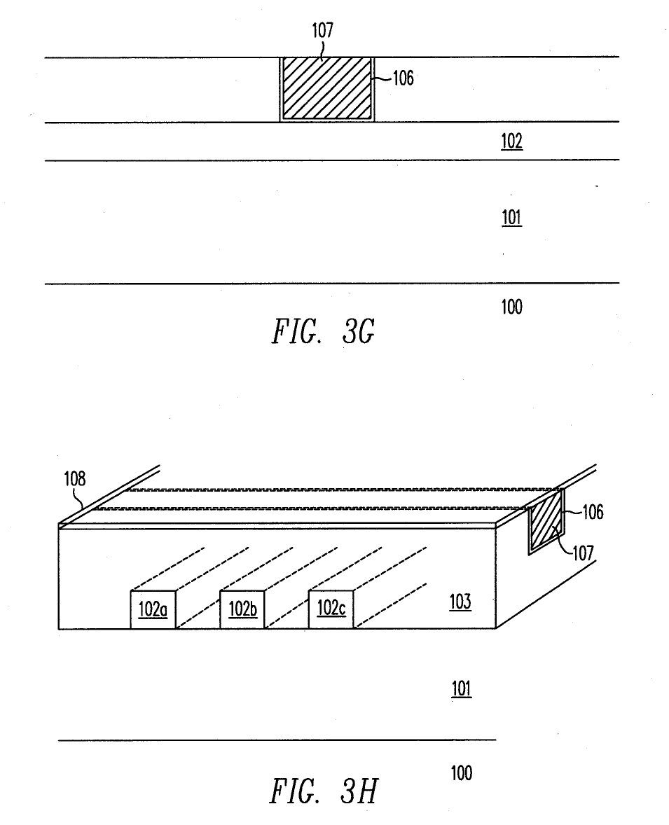

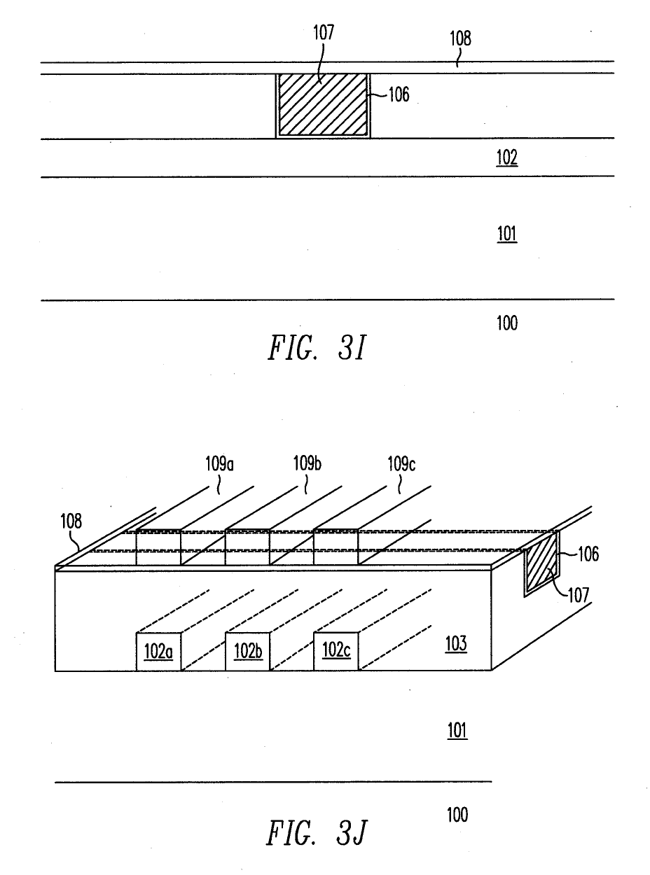

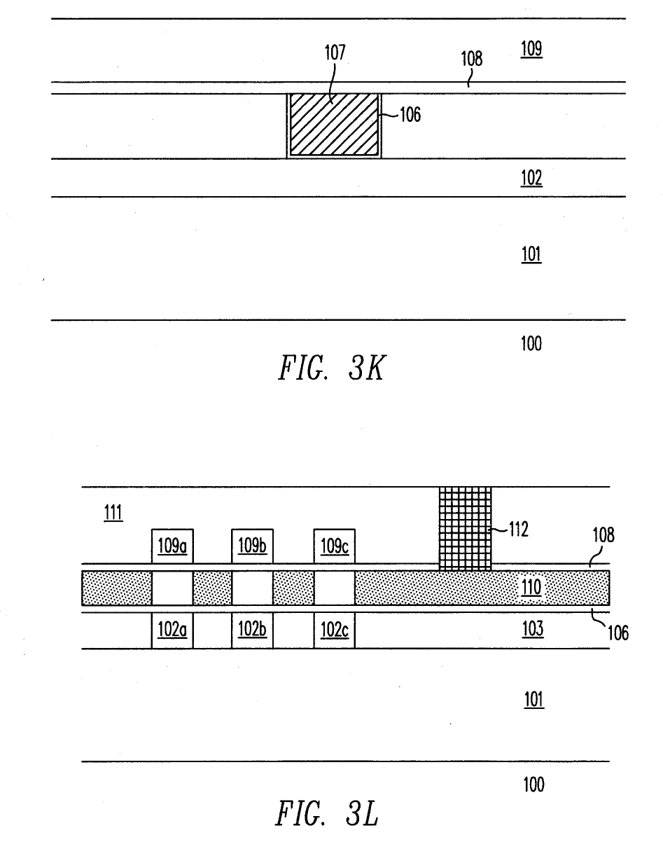

FIG. 2 shows antimony profiles after implantation and annealing steps. In FIG. 2, three profiles are shown: (a) for a wafer implanted to about 10²⁰ atoms/cm³ at a depth of 40 nm, without further processing; (b) for a wafer implanted as in (a), but subjected to a 675° C. oxidation step for 80 minutes, followed by a 30-second RTA step in nitrogen at 700° C.; and (c) for a wafer implanted as in (a), but subjected to a 675° C. oxidation step for 80 minutes, followed by a 30-second RTA step in nitrogen at 800° C. As shown in FIG. 3, no significant dopant movements were found even after the 80-minute, 675° C. oxidation step and the 800° C. RTA step for 30 seconds. The data for the wafer as implanted without further processing is compensated by −4 nm to make comparable with the other wafers, which each have 4 nm of thermal oxide removed.

FIGS. 3A-3L illustrate a method suitable for forming a NAND-type non-volatile semiconductor memory device using antimony, according to one embodiment of the present invention.

FIG. 3A shows insulating layer 101 provided on substrate 100. Substrate 100 may be a semiconductor wafer containing integrated circuitry for controlling a non-volatile memory. The semiconductor wafer may be either of a bulk type, where the substrate is made of a single crystal of semiconductor, such as silicon, or of a semiconductor-on-insulator type, such as silicon on insulator (SOI), where the integrated circuitry is made in the thin top silicon layer. Insulating layer may be planarized using conventional chemical mechanical polishing (CMP). Within insulating layer 101 may be embedded vertical interconnections (not shown in FIG. 3) for connecting the integrated circuitry with the non-volatile memory device. Such interconnections may be made using conventional photolithographic and etch techniques to create contact holes, followed by filling the contact holes with a suitable type of conductor, such as a combination of titanium nitride (TiN) and tungsten (W), or a heavily doped polysilicon.

Next, a conducting material 102 is provided on top of insulating layer 101 using conventional deposition techniques. Material 102 may also comprise a stack of two or more conducting materials formed in succession. Suitable materials for material 102 include heavily doped polysilicon, titanium disilicide (TiSi₂), tungsten (W), tungsten nitride (WN), cobalt silicide (CoSi₂), nickel silicide (NiSi) or combinations of these materials. Conventional photolithographic and etch techniques are used to pattern gate electrode word lines 102a, 102b and 102c, as shown in FIG. 3B. These word lines form the gate electrode word lines for the access devices to be formed, according to one embodiment of the present invention.

Next, an insulating layer 103 is provided over word lines 102a, 102b and 102c. Insulating layer 103 may be provided using high density plasma (HDP), chemical vapor deposition (CVD), plasma enhanced CVD (PECVD), physical vapor deposition (PVD) or may be a spin on glass (SOG). The surface is then planarized using a conventional CMP step, which either may polish insulating layer 103 down to the surface of the word lines 102a, 102b and 102c, or timed such that a controlled thickness remains of insulating layer 103 between the surface of the word lines 102a, 102b and 102c and the top polished surface of insulating layer 103. In the former case, after CMP, a controlled thickness of an insulating material is deposited using one of the techniques discussed above. Under either approach, the result is shown in FIG. 3C.

Next, trenches 105 are etched into insulating layer 103 using conventional photolithographic and etch techniques. The etching exposes at least the surface of the word lines 102a, 102b and 102c and removes a portion of insulating layer 103. Over-etching may also take place, so long as no detriment is made to the electrical working of the eventual completed structure. FIG. 3D shows trench 105 after formation. The trenches are formed in a direction perpendicular to word lines 102a, 102b and 102c. FIG. 3E shows a cross section through both trench 105 and word line 102, which runs along the plane of FIG. 3E. Trench 105 may be 50 Å to 3000 Å thick, preferably about 500 Å. Trenches 105 may be formed in a trench etch which also removes a portion of each word line 102. Such an etch may be achieved by over-etching (using plasma etching, for example) of insulating material 105 into a portion of word lines 102. Thus, the bottom of trench 105 may be situated below the top surface of each word line 102.

Next, thin dielectric layer 106 is formed on top of the structure shown in FIG. 3E. Thin dielectric layer 106 forms the gate dielectric of the access device and may be formed using a conventional method, such as thermal oxidation in an oxidizing ambient, low pressure CVD (LPCVD) deposition of a dielectric material, such as silicon dioxide, silicon nitride, silicon oxynitride, high temperature oxide (HTO), PECVD dielectric (e.g., silicon oxide or silicon nitride), atomic layer deposition (ALD) of silicon oxide, or some high-k dielectric material. The effective oxide thickness may be in the range of 10 Å and 400 Å.

Next, active semiconductor layer 107 is formed by depositing a semiconductor material, such as polycrystalline silicon (polysilicon), polycrystalline germanium, amorphous silicon, amorphous germanium or a combination of silicon and germanium, using conventional techniques such as LPCVD or PECVD. Polycrystalline material may be deposited as a first step as an amorphous material. The amorphous material may then be crystallized using heat treatment or laser irradiation. The material is formed sufficiently thick, so as to completely fill trench 105 (e.g., at least half the width of trench 105). After deposition, the part of the semiconductor material above trench 105 is removed using, for example, either CMP, or plasma etching. Using either technique, the semiconductor material can be removed with very high selectivity relative to insulating layer 103. For example, CMP of polysilicon can be achieved with selectivity with respect to silicon oxide of several hundred to one. The representative result using either technique is shown in FIG. 3F.

FIG. 3G shows a cross section made through trench 105 and word line 102. Word line 102 runs in a direction parallel to the cross section plane of FIG. 3G. Thin dielectric layer 106 forms the gate dielectric layer of the access device and material 107 is the semiconductor material remaining in trench 105 after the material is substantially removed from the surface of insulating layer 103. Material 107 forms the active semiconductor layer for both the memory device and the access device of the dual-gate device. Material 107 may be undoped or may be doped using conventional methods, such as ion implantation, or in-situ doping carried out in conjunction with material deposition. A suitable doping concentration is betwen zero (i.e., undoped) and 5×10¹⁸ /cm³, and may be p-type for an NMOS implementation.

Next, dielectric layer 108 is provided, as shown in FIG. 3H. Dielectric layer 108, which is the dielectric layer for the memory device in the dual-gate device, may be a composite ONO layer consisting of a bottom 10 Å to 80 Å thick thin silicon oxide, an intermediate 20 Å to 200 Å silicon nitride layer, and a top 20 Å to 100 Å silicon oxide layer. (Other materials may take the place of the silicon nitride layer, such as silicon oxynitride, silicon-rich silicon nitride, or a silicon nitride layer that has spatial variations in silicon and oxygen content.) Conventional techniques may be used to form these layers. The bottom thin silicon oxide layer may be formed using thermal oxidation in an oxidizing ambient, low pressure oxidation in a steam ambient, or LPCVD techniques that deposits a thin layer of silicon oxide, such as high temperature oxide (HTO). Atomic layer deposition (ALD) may also be used to form the bottom thin silicon oxide layer. The intermediate layer may be formed using LPCVD techniques or PECVD techniques. The top silicon oxide layer may be formed using, for example, LPCVD techniques, such as HTO, or by depositing a thin amorphous silicon layer, followed by a silicon oxidation in an oxidizing ambient.

Alternatively, dielectric layer 108 may be a composite layer consisting of silicon oxide, silicon nitride, silicon oxide, silicon nitride and silicon oxide (ONONO), using the techniques discussed above. As discussed above, the silicon nitride may be replaced by silicon oxynitride, silicon-rich silicon nitride, or a silicon nitride layer that has spatial variations in silicon and oxygen content. Alternatively, an ONONONO layer may be used. Such multiplayer composites may be tailored such that the electric charge stored within dielectric layer 108 persists for longer periods.

Alternatively, dielectric layer 108 may contain a floating gate conductor for charge storage that is electrically isolated from both the gate electrode of the memory device to be formed and the active semiconductor layer. The floating gate conductor may comprise nano-crystals that are placed between the gate electrode and the active semiconductor layer 107. Suitable conductors may be silicon, germanium, tungsten, or tungsten nitride.

Alternatively to charge storage in dielectric layer 108, the threshold voltage shifts may also be achieved by embedding a ferroelectric material whose electric polarization vector can be aligned to a predetermined direction by applying a suitable electric field.

FIG. 31 shows a cross section of the forming dual-gate structure through word line 102, after the step forming dielectric layer 108.

Next, conducting material 109 is provided over dielectric layer 108 using conventional deposition techniques. Conducting material 109 may comprise a stack of two or more conducting materials. Suitable materials for conducting material 109 include heavily doped polysilicon, titanium disilicide (TiSi₂), tungsten (W), tungsten nitride (WN), cobalt silicide (CoSi₂), nickel silicide (NiSi) or combinations of these materials. Conventional photolithographic and etch techniques are used to form gate electrode word lines 109a, 109b and 109c, as is shown in FIG. 3J. These word lines form the gate electrode word lines of the forming memory devices, and run substantially parallel to the underlying access gate electrode word lines 102a, 102b and 102c. FIG. 3K shows a cross section through word lines 102 and 109, after the step forming word lines 109a, 109b and 109c.

Next, source and drain regions are formed within active semiconductor layer 107 using ion implantation. In this embodiment, antimony ions may be implanted at a dose between 1×10¹²/cm² and 1×10¹⁶/cm². The ion implantation provides source and drain regions that are self-aligned to the gate electrode word lines 109a, 109b and 109c. The result is illustrated in FIG. 3L in which regions 110 represent the heavily doped source and drain regions. In one embodiment, these source and drain regions extend from the top surface of active semiconductor layer 107 to its bottom surface. The source and drain regions may be formed using a combination of ion implantation and subsequent thermal steps to activate the dopant atoms introduced. In one embodiment, a 30-second RTA step in nitrogen ambient at a temperature of 850° C. or less may be used.

Next, insulating layer 111 may be provided using high density plasma (HDP), CVD, PECVD, PVD or a spin on glass (SOG). The surface may then be planarized using a conventional CMP step. The result is shown in FIG. 3L.

Vertical interconnections 112 may then be formed using conventional photolithographic and plasma etching techniques to form small holes down to gate electrodes 109a, 109b 109c, heavily doped semiconductor active regions 110 and gate electrodes 102a, 102b and 102c. The resulting holes are filled with a conductor using conventional methods, such as tungsten deposition (after an adhesion layer of titanium nitride has been formed) and CMP, or heavily doped polysilicon, followed by plasma etch back or CMP. The result is shown in FIG. 3L.

Subsequent steps may be carried out to further interconnect the dual-gate devices with other dual-gate devices in the same layer or in different layers and with the circuitry formed in the substrate 100.

FIG. 3 therefore illustrates forming a dual-gate memory device with access gate 102, access gate dielectric 106, semiconductor active region 107, memory dielectric 108, memory gate electrode 109 and source and drain regions 110.

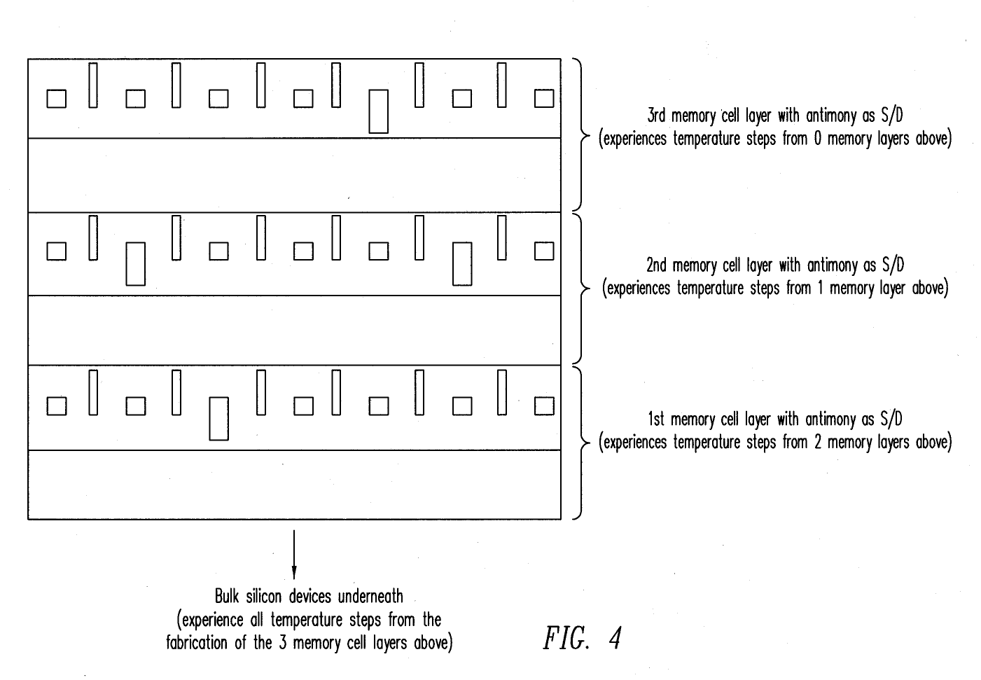

Based on the teachings above, very high density semiconductor devices may be formed by repetitively carrying out the steps of FIGS. 3A to 3L to form multiple levels of the structures of the dual-gate devices discussed above. FIG. 4 shows a 3-D stack of dual-gate memory cells (3 layer), illustrating that the implanted antimony dopant profile is substantially retained in each layer over the various temperature cycles experienced in their fabrication.

The above detailed description is provided to illustrate specific embodiments of the present invention and is not intended to be limiting. Numerous variations and modifications within the scope of the present invention are possible. The present invention is set forth in the following claims.

1. A multi-layer semiconductor device, including:
a plurality of layers of dual-gate devices, each dual gate device comprising:
an active semiconductor layer, comprising a deposited polycrystalline semiconductor material, having a first surface and a second surface provided on opposite sides of the active semiconductor layer, and having formed therein first and second antimony-doped regions that are spaced apart;
a first dielectric layer adjacent the first surface;
a second dielectric layer adjacent the second surface;
a first gate structure provided on the first dielectric layer adjacent the first surface of the active semiconductor layer; and
a second gate structure provided on the second dielectric layer adjacent the second surface of the active semiconductor layer.

2. A multi-layer semiconductor device as in claim 1, wherein the peak dopant density in each antimony-doped region is between 10¹⁷ atoms/cm³ and 10²¹ atoms/cm³.

3. A multi-layer semiconductor device as in claim 1, wherein the antimony-doped regions are formed by ion implantation using the first gate structure as a mask.

4. A multi-layer semiconductor device as in claim 1, wherein the dopants in the antimony-doped regions are activated using rapid thermal annealing.

5. A multi-layer semiconductor device as in claim 4, wherein the rapid thermal annealing is carried out under a halogen lamp.

6. A multi-layer semiconductor device as in claim 1, wherein the dopants in the antimony-doped regions are activated at a temperature between 600° C. to 900° C.

7. A multi-layer semiconductor device as in claim 1, wherein the dual-gate device comprises a non-volatile memory cell.

8. A multi-layer semiconductor device as in claim 1, wherein each layer of dual-gate devices comprises a plurality of dual-gate devices serially connected to form a NAND-type memory string.
